(19) United States
(12) Patent Application Publication
(10) Pub. No.: US 2015/0214361 A1
(43) Pub. Date: Jul. 30, 2015

(54) Semiconductor Device Having Partial Insulation Structure And Method Of Fabricating Same

(71) Applicant: Macronix International Co., Ltd., Hsinchu (TW)

(72) Inventors: Ching-Lin CHAN, Huwei Township (TW); Cheng-Chi LIN, Toucheng Township (TW); Shih-Chin LIEN, Sinjhuang City (TW); Shyi-Yuan WU, Hsinchu City (TW)

(73) Assignee: Macronix International Co., Ltd., Hsinchu (TW)

(21) Appl. No.: 14/168,969

(22) Filed: Jan. 30, 2014

(51) Int. Cl. H01L 29/78; H01L 29/66

(52) U.S. Cl. CPC H01L 29/7823; H01L 29/66681

(57) ABSTRACT

A method for fabricating a semiconductor device includes providing a substrate having a first conductive type, forming a high-voltage well having a second conductive type in the substrate, forming a drift region in the high-voltage well, and forming an insulation layer on the substrate. The insulation layer includes a first insulation portion and a second insulation portion respectively covering opposite edge portions of the drift region, and not covering a top portion of the drift region.

### FIELD OF THE DISCLOSURE

The present disclosure relates to a semiconductor device and a method of fabricating the same and, more particularly, to a semiconductor device having an insulation structure and a method of fabricating the same.

### BACKGROUND OF THE DISCLOSURE

A lateral drain metal-oxide-semiconductor (LDMOS) device is a high voltage device widely used in display devices, portable devices, and many other applications. Design goals of the LDMOS device include a high breakdown voltage and a low specific on-resistance.

The specific on-resistance of the LDMOS device is limited by a doping concentration of a grade region of the device. When the doping concentration of the grade region decreases, the specific on-resistance increases.

### SUMMARY

According to an embodiment of the disclosure, a method for fabricating a semiconductor device includes providing a substrate having a first conductive type, forming a high-voltage well having a second conductive type in the substrate, forming a drift region in the high-voltage well, and forming an insulation layer on the substrate. The insulation layer includes a first insulation portion and a second insulation portion respectively covering opposite edge portions of the drift region, and not covering a top portion of the drift region.

According to another embodiment of the disclosure, a semiconductor device includes a substrate having a first conductive type, a high-voltage well having a second conductive type and disposed in the substrate, a drift region disposed in the high-voltage well, a partial insulation structure disposed on edge portions of the drift region, and a drain region disposed in the high-voltage well and spaced apart from the drift region.

### BRIEF DESCRIPTION OF THE DRAWINGS

FIG. 1A is a top view of a LDMOS device according to an embodiment.

FIG. 16 is a cross-sectional view of the LDMOS device along line B-B′ of FIG. 1A.

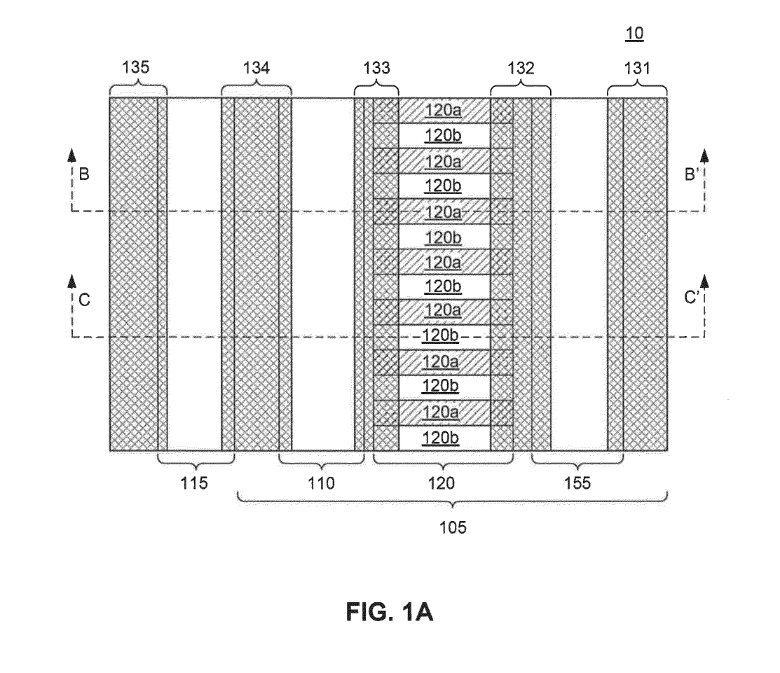

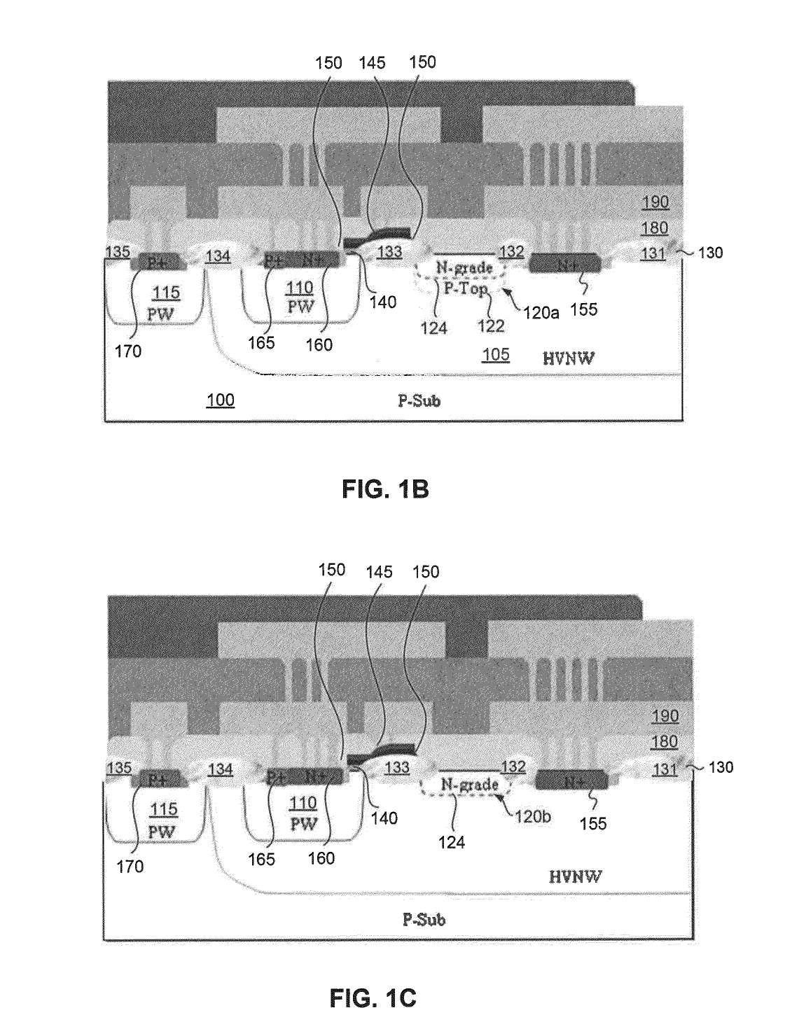

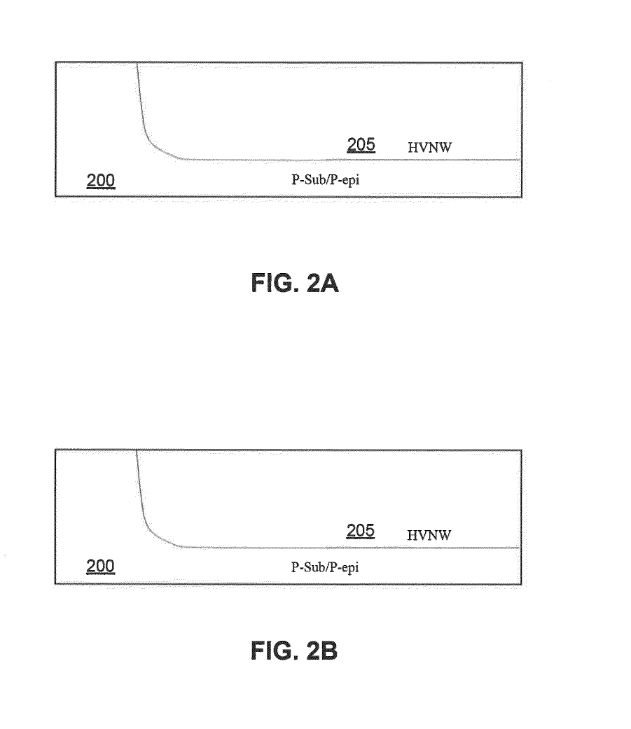

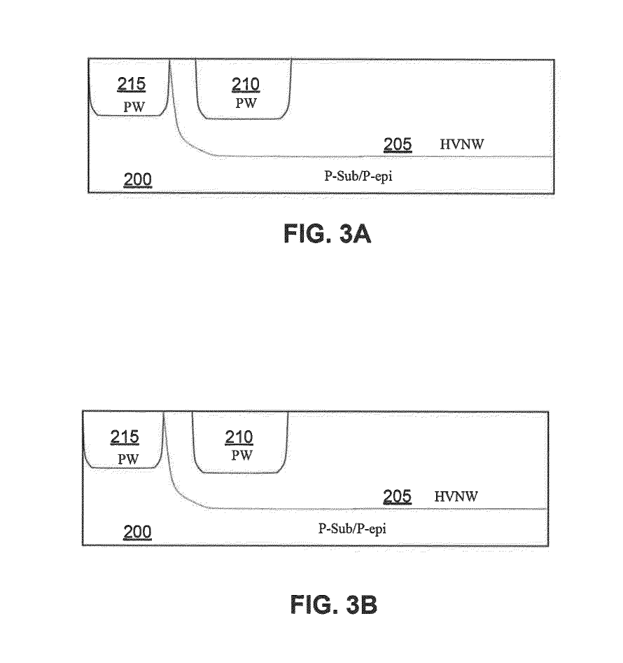

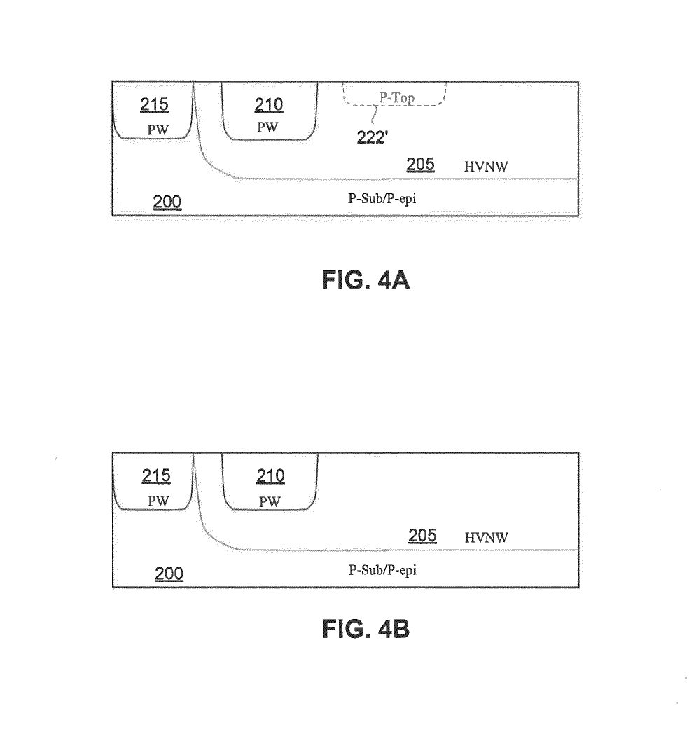

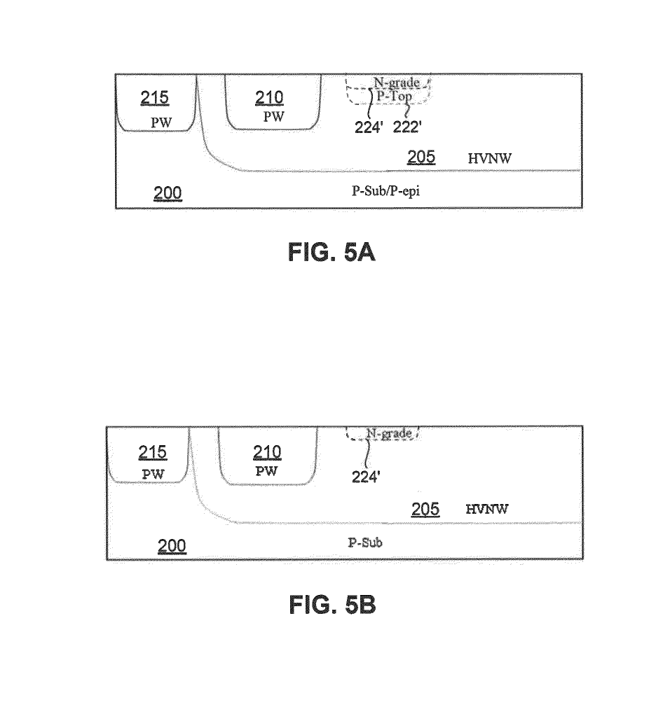

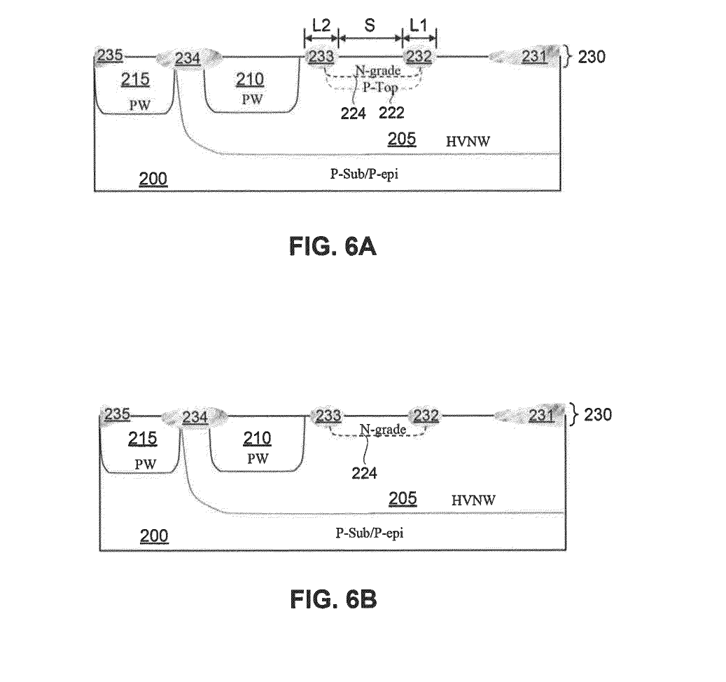

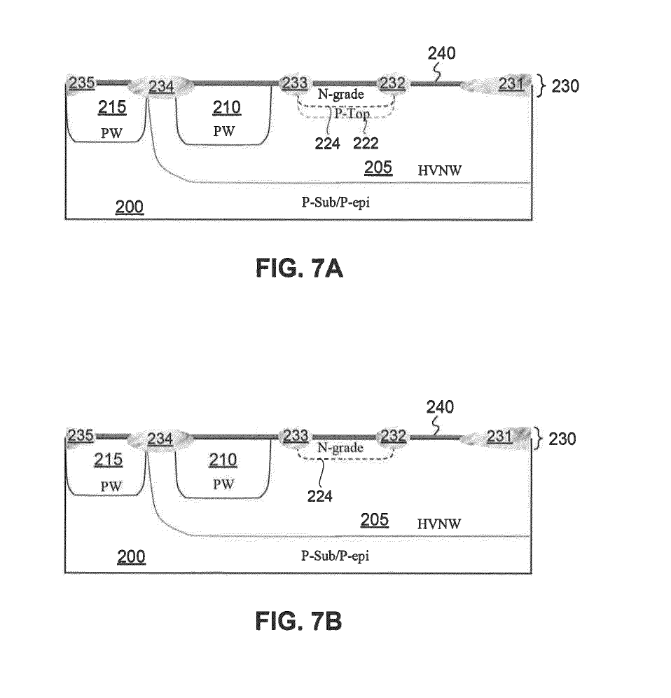

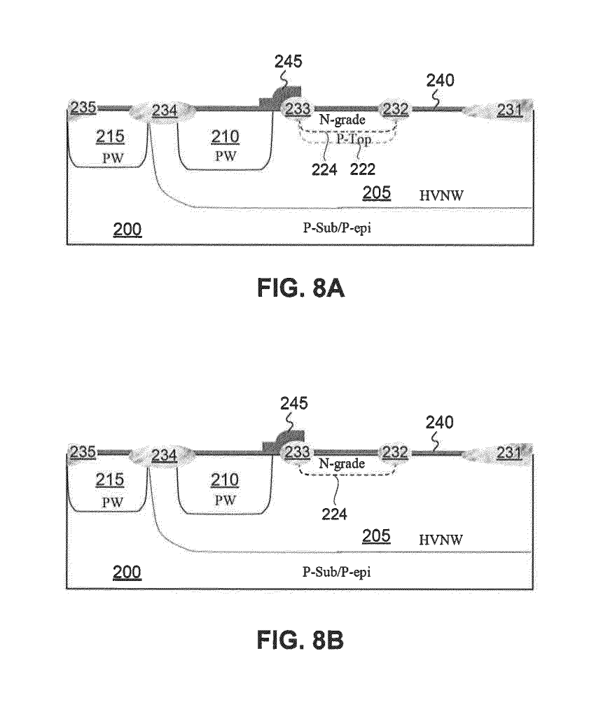

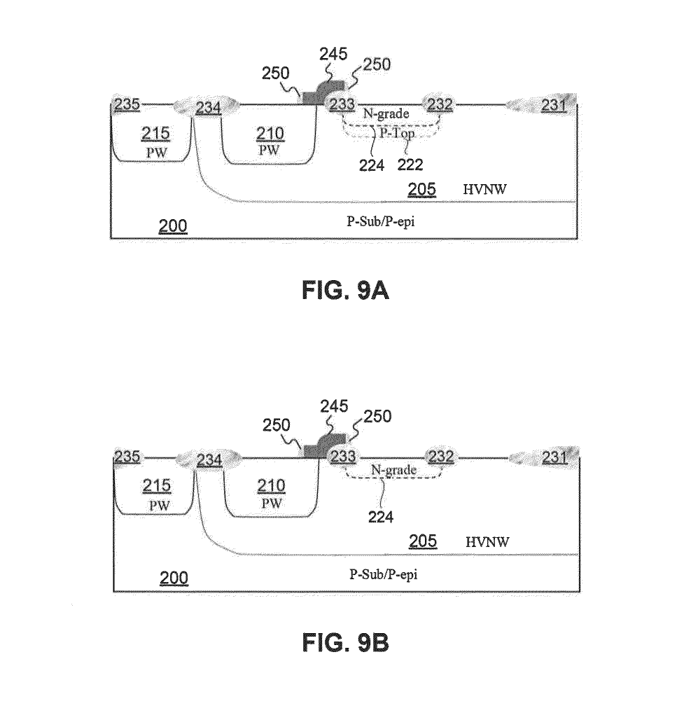

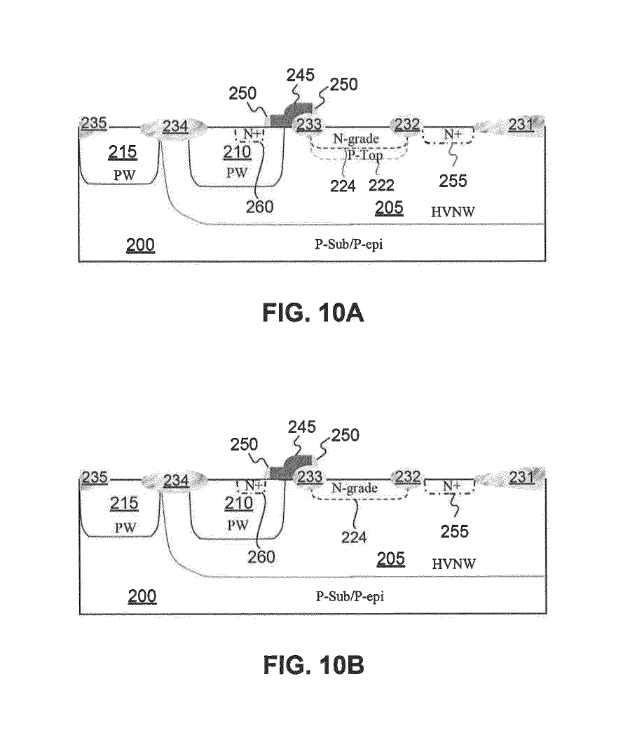

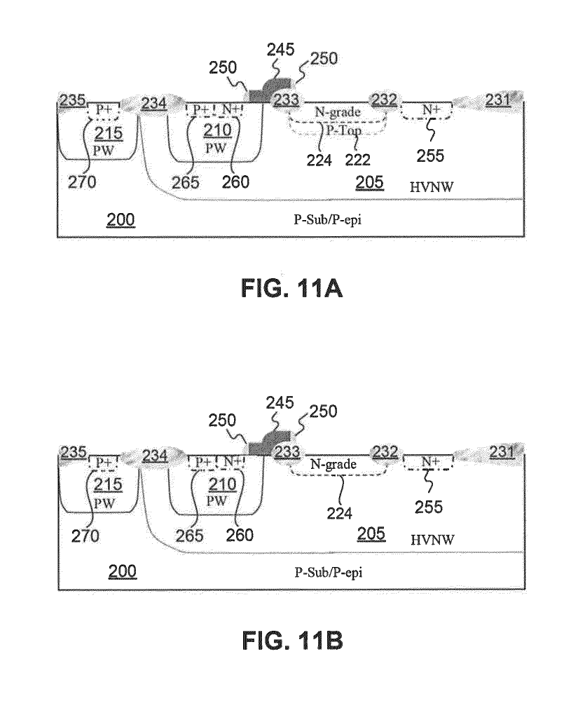

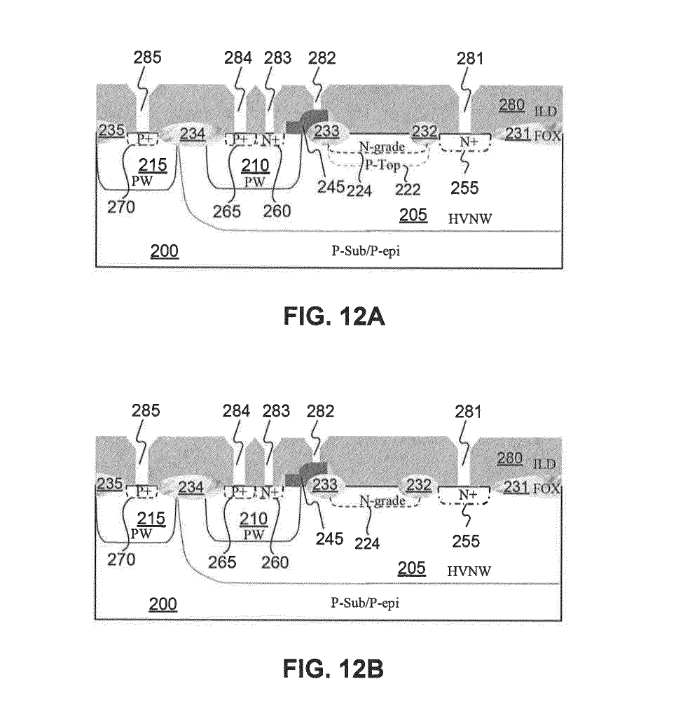

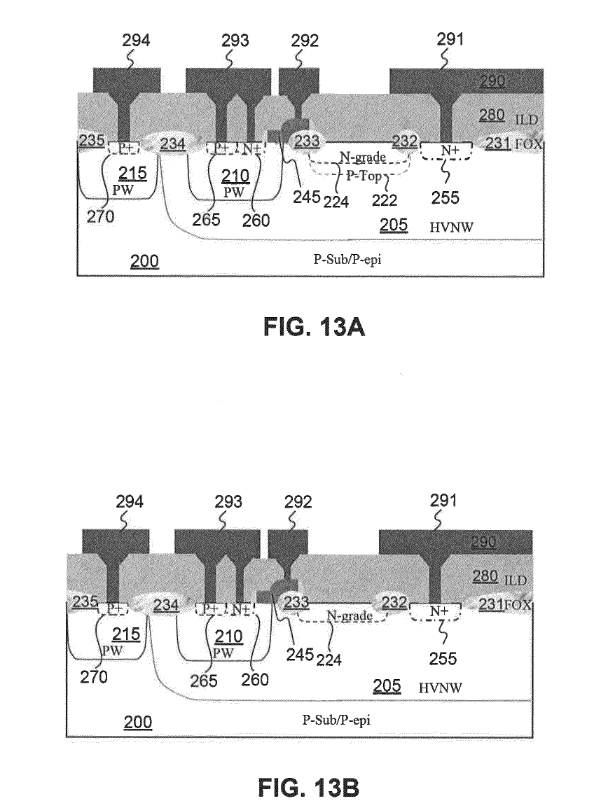

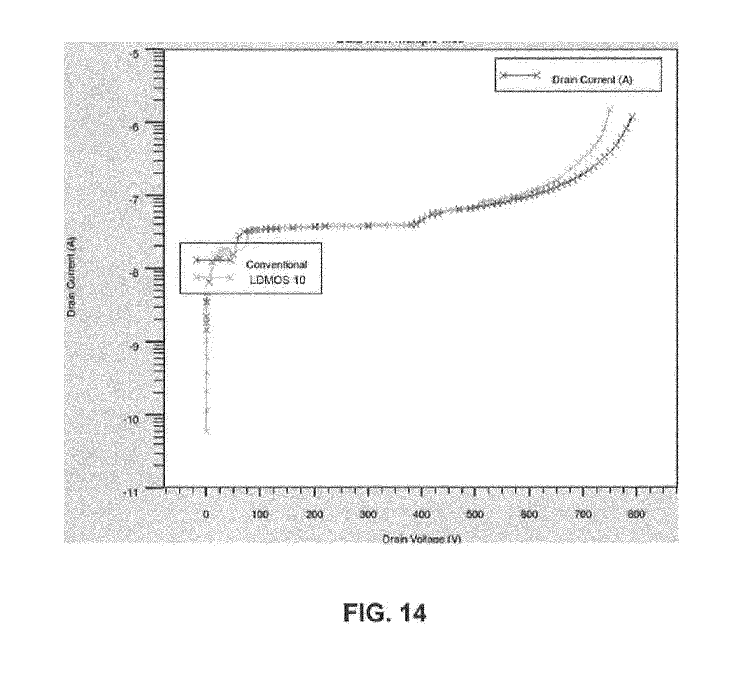

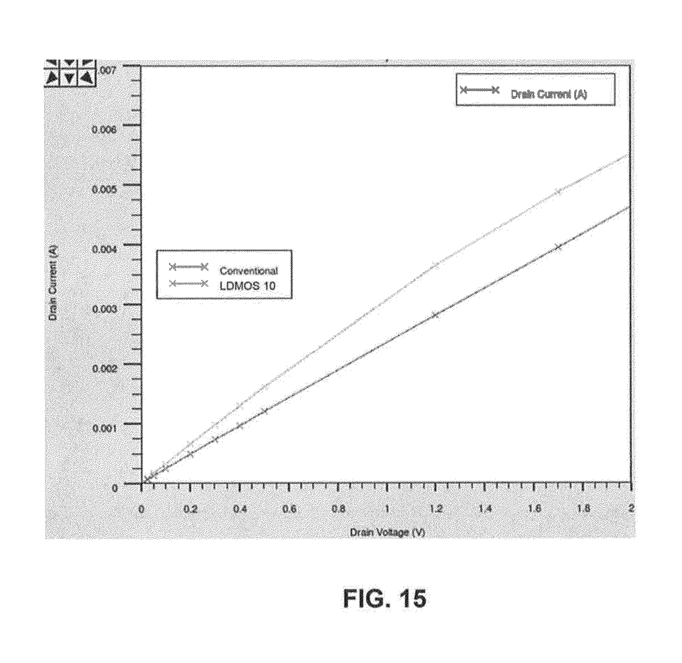

FIG. 1C is a cross-sectional view of the LDMOS device along line C-C′ of FIG. 1A.

FIGS. 2A-13B schematically illustrate a process of fabricating the LDMOS device of FIGS. 1A-1C, according to an embodiment.

FIG. 14 is a graph showing drain characteristics of the LDMOS device of FIGS. 1A-1C, and a conventional device constructed as a comparative example.

FIG. 15 is a graph showing drain characteristics of the LDMOS device of FIGS. 1A-1C, and a conventional device constructed as a comparative example.

### DETAILED DESCRIPTION

Reference will now be made in detail to the present embodiments, examples of which are illustrated in the accompanying drawings. Wherever possible, the same reference numbers will be used throughout the drawings to refer to the same or like parts.

FIG. 1A schematically illustrates a top view of a LDMOS device 10 according to an embodiment. FIG. 1B is a cross-sectional view of LDMOS device 10 along line B-B′ of FIG. 1A. FIG. 1C is a cross-sectional view of LDMOS device 10 along line C-C′ of FIG. 1A.

As illustrated in FIGS. 1A-1C, LDMOS device 10 includes a P-type substrate 100, a high-voltage N-well (HVNW) 105 formed in substrate 100, a first P-well 110 formed in HVNW 105, a second P-well 115 formed outside and adjacent to HVNW 105, a drift region 120 formed in HVNW 105 on a side (e.g., right side) of and spaced apart from first P-well 110, and an insulation layer 130 disposed on substrate 100. Drift region 120 includes a plurality of alternately arranged first sections 120a and second sections 120b. Each first section 120a includes a P-top region 122 and an N-grade region 124 disposed on P-top region 122. Each second section 120b includes N-grade region 124. Insulation layer 130 can be made of field oxide (FOX). Hereinafter, insulation layer 130 is referred to as FOX layer 130. FOX layer 130 includes a first FOX portion 131 spaced apart from drift region 120, a second FOX portion 132 covering a first-side (e.g., right-side) edge portion of drift region 120, a third FOX portion 133 covering a second-side (e.g., left-side) edge portion of drift region 120, a fourth FOX portion 134 covering a portion of HVNW 105 between first P-well region 110 and second P-well region 115, and a fifth FOX portion 135 covering a side (e.g., left-side) edge portion of second P-well region 115. A central portion of drift region 120 is not covered by FOX layer 130.

LDMOS device 10 also includes a gate oxide layer 140 overlying a side (e.g., left-side) portion of third FOX portion 133 and the side (e.g., right-side) edge portion of first P-well region 110, a gate layer 145 disposed on gate oxide layer 140, spacers 150 disposed on side walls of gate layer 145, a first N⁺-region 155 formed in HVNW 105 between first FOX portion 131 and second FOX portion 132, a second N⁺-region 160 formed in first P-well 110 adjacent to a side (e.g., left-side) edge portion of gate layer 145, a first P⁺-region 165 formed in first P-well 110 adjacent to second N⁺-region 160, and a second P⁺-region 170 formed in second P-well 115 between fourth FOX portion 134 and fifth FOX portion 135. First N⁺-region 155 constitutes a drain region of LDMOS device 10. Second N⁺-region 160 and first P⁺-region 165 constitute a source region of LDMOS device 10. Second P⁺-region 170 constitutes a bulk region of LDMOS device 10.

LDMOS device 10 further includes an interlayer dielectric (ILD) layer 180 formed on substrate 100, and a contact layer 190 formed on ILD layer 180. Contact layer 190 includes a plurality of isolated contact portions for contacting different portions of the structures formed in substrate 100 via different openings formed in ILD layer 180.

In LDMOS device 10, second FOX portion 132 and third FOX portion 133 form a partial insulation structure. As will be explained in detail with reference to a fabrication process of LDMOS device 10, the partial insulation structure assists in increasing a doping concentration of N-grade region 124.

FIGS. 2A-13B schematically illustrate a process of fabricating LDMOS device 10 of FIGS. 1A-1C, according to an embodiment. FIGS. 2A, 3A, 4A, . . . , 13A schematically illustrate partial cross-sectional views of LDMOS device 10 taken along line B-B′ of FIG. 1A during steps of the process of fabricating LDMOS device 10. FIGS. 2B, 3B, 4B, . . . , 13B schematically illustrate partial cross-sectional views of LDMOS device 10 taken along line C-C′ of FIG. 1A during steps of the process of fabricating LDMOS device 10.

First, referring to FIGS. 2A and 2B, a substrate 200 having a first conductive type is provided, and a deep well 205 having a second conductive type is formed in substrate 200 and extends downward from a top surface of substrate 200. The first conductive type can be P-type, and the second conductive type can be N-type. Hereinafter, deep well 205 is referred to as a high-voltage N-well (HVNW) 205. Substrate 200 can be formed of a P-type bulk silicon material, a P-type epitaxial layer, or a P-type silicon-on-insulator (SOI) material. HVNW 205 can be formed by a photolithography process, an ion implantation process for implanting an N-type dopant (e.g., phosphorus or arsenic) at a concentration of about 10¹¹ to 10¹³ atoms/cm², and a heating process for driving-in the implanted dopant to reach a predetermined depth.

Referring to FIGS. 3A and 3B, a first P-well 210 is formed in HVNW 205, close to an edge portion of HVNW 205. A second P-well 215 is formed in substrate 200, outside and adjacent to the edge portion of HVNW 205. First P-well 210 and second P-well 215 can be formed by a photolithography process, an ion implantation process for implanting a P-type dopant (e.g., boron) at a concentration of about 10¹² to 10¹⁴ atoms/cm², and a heating process for driving-in the implanted dopant to reach a predetermined depth.

Referring to FIGS. 4A and 4B, a P-top implantation region 222′ is formed in HVNW 205, in regions corresponding to first sections 120a illustrated in FIG. 1A. No P-top implantation region 222′ is formed in regions corresponding to second sections 120b illustrated in FIG. 1A. P-top implantation region 222′ can be formed by a photolithography process for defining first sections 120a and second sections 120b, and an ion implantation process for implanting a P-type dopant (e.g., boron) into first sections 120a at a concentration of about 10¹¹ to 10¹⁴ atoms/cm².

Referring to FIGS. 5A and 5B, an N-grade implantation region 224′ is formed in HVNW 205, in a region corresponding to both first section 120a and second section 120b illustrated in FIG. 1A. N-grade implantation region 224′ can be formed by a photolithography process and an ion implantation process for implanting an N-type dopant (e.g., phosphorus or arsenic) at a concentration of about 10¹¹ to 10¹⁴ atoms/cm².

Referring to FIGS. 6A and 6B, an insulation layer in the form of a field oxide (FOX) layer 230 is formed on the top surface of substrate 200. FOX layer 230 includes a first FOX portion 231 covering a right edge portion of HVNW 205, a second FOX portion 232 covering right edge portions of P-top implantation region 222′ and N-grade implantation region 224′, a third FOX portion 233 covering left edge portions of P-top implantation region 222′ and N-grade implantation region 224′, a fourth FOX portion 234 covering a left edge portion of HVNW 205 between first P-well 210 and second P-well 215, and a fifth FOX portion 235 covering a left edge portion of second P-well 215.

FOX layer 230 can be formed by a photolithography process, an etching process, and a thermal oxidation process. During the thermal oxidation process for forming FOX layer 230, the P-type dopant in P-top implantation region 222′ and the N-type dopant in N-grade implantation region 224′ are driven to predetermined depths in HVNW 205 to form P-top region 222 and N-grade region 224, respectively. The depth of P-top region 222 can be about 0.5 μm to 3 μm. The depth of N-grade region 224 can be about 0.1 μm to 1 μm.

Second FOX portion 232 and third FOX portion 233 constitute a partial insulation structure that prevents the doping concentration of P-top region 222 from decreasing. If a FOX portion is formed to cover the entire P-top implantation region 222′ and N-grade implantation region 224′, the boron atoms (i.e., the P-type dopant) in P-top implantation region 222′ could diffuse into the FOX portion, decreasing the doping concentration in the resulting P-top region 222. Such decreasing in the doping concentration in P-top region 222 could decrease the doping concentration in N-grade region 224, because the maximum doping concentration in N-grade region 224 is limited by the doping concentration in P-top region 222 in order to form a full depletion region. Such decreasing in the doping concentration in N-grade region 224 results in a high specific on-resistance of the device. On the other hand, the partial insulation structure according to the embodiment does not include a FOX portion on top of P-top implantation region 222′, and thus the diffusion of the boron atoms can be reduced.

As illustrated in FIG. 6A, second FOX portion 232 has a length of L1, and third FOX portion 233 has a length of L2. Length L1 of second FOX portion 232 can be different from length L2 of third FOX portion 233. In addition, a space S between second FOX portion 232 and third FOX portion 233 is variable in view of various design considerations, such as the doping concentration in N-grade region 224, and the structure and/or application of LDMOS device 10.

Referring to FIGS. 7A and 7B, a gate oxide layer 240 is formed on surface portions of the structure of FIGS. 6A and 6B that are not covered by FOX layer 230. That is, gate oxide layer 240 is formed between first FOX portion 231 and second FOX portion 232, between second FOX portion 232 and third FOX portion 233 and covering N-grade region 224, between third FOX portion 233 and fourth FOX portion 234, and between fourth FOX portion 234 and fifth FOX portion 235. Gate oxide layer 240 can be formed by a sacrificial oxidation process to form a sacrificial oxide layer, a cleaning process to remove the sacrificial oxide layer, and an oxidation process to form an oxide layer.

Referring to FIGS. 8A and 8B, a gate layer 245 is formed on gate oxide layer 240, overlying a left portion of third FOX portion 233 and a right portion of first P-well region 210. Gate layer 245 can include a polysilicon layer and a tungsten silicide layer formed on the polysilicon layer. The thickness of gate layer 245 can be about 0.1 μm to 0.7 μm. Gate layer 245 can be formed by a deposition process for depositing a polysilicon layer and a tungsten silicide layer, a photolithography process, and an etching process.

Referring to FIGS. 9A and 9B, spacers 250 are formed on both sides of gate layer 245. Spacers 250 can be tetraethoxysilane (TEOS) oxide films. Spacers 250 can be formed by a deposition process, a photolithography process, and an etching process. After forming spacers 250, all of gate oxide layer 240 is removed by etching except for the portion under gate layer 245.

Referring to FIGS. 10A and 10B, a first N⁺-region 255 is formed in HVNW 205 between first FOX portion 231 and second FOX portion 232, and a second N⁺-region 260 is formed in first P-well 210 adjacent to a left edge portion of gate layer 245. First N⁺-region 255 and second N⁺-region 260 can be formed by a photolithography process and an ion implantation process for implanting a N-type dopant (e.g., phosphorus or arsenic) at a concentration of about 10¹⁵ to 10¹⁶ atoms/cm².

Referring to FIGS. 11A and 11B, a first P⁺-region 265 is formed in first P-well 210 adjacent to second N⁺-region 260, and a second P⁺-region 270 is formed in second P-well 215 between fourth FOX portion 234 and fifth FOX portion 235. First P⁺-region 265 and second P⁺-region 270 can be formed by a photolithography process and an ion implantation process for implanting a P-type dopant (e.g., boron) at a concentration of about 10′⁵ to 10¹⁶ atoms/cm².

Referring to FIGS. 12A and 12B, an interlayer dielectric (ILD) layer 280 is formed on the entire surface of the structure of FIGS. 11A and 11B, ILD layer 280 includes a first opening 281 that is vertically aligned with first N⁺-region 255, a second opening 282 that is vertically aligned with gate layer 245, a third opening 283 that is vertically aligned with second N⁺-region 260, a fourth opening 284 that is vertically aligned with first P⁺-region 265, and a fifth opening 285 that is vertically aligned with second P⁺-region 270. ILD layer 280 can include undoped silicate glass (USG) and/or borophosphosilicate glass (BPSG). The thickness of ILD layer 280 can be 0.5 μm to 2 μm. ILD layer 280 can be formed by a deposition process for depositing a layer of USG and BPSG, a photolithography process, and an etching process for forming openings 281 through 285.

Referring to FIGS. 13A and 13B, a contact layer 290 is formed on the structure of FIGS. 12A and 12B. Contact layer 290 includes a first contact portion 291 that contacts first N⁺-region 255, a second contact portion 292 that contacts gate layer 245, a third contact portion 293 that contacts both second N⁺-region 260 and first P⁺-region 265, and a fourth contact portion 294 that contacts second P⁺-region 270. Contact layer 290 can be made of metal, such as aluminum, or an aluminum-copper alloy. Contact layer 290 can be formed by a deposition process, a photolithography process, and an etching process.

FIG. 14 is a graph showing drain characteristics of LDMOS device 10 having the partial insulation structure as illustrated in FIGS. 1A-1C, and a conventional device constructed as a comparative example. In the conventional device, a FOX layer covers the entire drift region 120. In FIG. 14, a drain-source voltage V_{DS} varies from 0 to 800V, and a gate-source voltage V_{GS} and a bulk-source voltage V_{BS} are maintained at 0V. As illustrated in FIG. 14, the off-breakdown voltage of both of LDMOS device 10 and the conventional device is above 700V. Therefore, LDMOS device 10 has the same off-breakdown voltage as that of the conventional device.

FIG. 15 is a graph showing the drain characteristics of the LDMOS device 10 and the conventional device. In FIG. 15, V_{DS} varies from 0 to 2V, and V_{GS} is maintained at 20V. As illustrated in FIG. 15, when V_{DS} is the same, a drain current I_{DS} of LDMOS 10 is higher than that of the conventional device. Therefore, LDMOS 10 has a lower specific on-resistance than that of the conventional device, while having the same off-breakdown voltage as that of the conventional device.

While the embodiment described above is directed to LDMOS device 10 shown in FIGS. 1A and 1B and fabrication methods thereof shown in FIGS. 2A-13B, those skilled in the art will now appreciate that the disclosed concepts are equally applicable to other semiconductor devices and the fabrication methods thereof, such as insulated-gate bipolar transistor (IGBT) devices and diodes.

In addition, while the partial insulation structure of LDMOS device 10 in the embodiment described above is made of field oxide, those skilled in the art will now appreciate that the partial insulation structure can be made of other suitable dielectric insulating structures, such as a shallow trench isolation (STI) structure.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method for fabricating a semiconductor device, the method comprising:
providing a substrate having a first conductive type;
forming a high-voltage well having a second conductive type in the substrate;
forming a drift region in the high-voltage well; and
forming an insulation layer on the substrate, the insulation layer including a first insulation portion and a second insulation portion respectively covering opposite edge portions of the drift region, and not covering a top portion of the drift region.

2. The method of claim 1, wherein the drift region includes a plurality of alternately arranged first sections and second sections,
the forming a drift region in the high-voltage well including:
forming a top region having the first conductive type in the first sections; and
forming a grade region having the second conductive type in both of the first sections and the second sections.

3. The method of claim 1, further including, before forming the drift region in the high-voltage well:
forming a first well having the first conductive type in the high-voltage well and close to an edge portion of the high-voltage well; and
forming a second well having the first conductive type outside and adjacent to the edge portion of the high-voltage well,
wherein the first well is spaced apart from the drift region.

4. The method of claim 3, wherein the insulation layer includes a third insulation portion covering a portion of the high-voltage well between the first well and the second well,
the method further including, after forming the insulation layer on the substrate:
forming a gate oxide layer between the first insulation portion and the second insulation portion, and between the second insulation portion and the third insulation portion;
forming a gate layer on the gate oxide layer on a portion of the high-voltage well between the drift region and the first well;
forming a drain region in the high-voltage well on a side of the drift region opposite to the first well;
forming a source region in the first well; and
forming a bulk region in the second well.

5. The method of claim 4, further including, after forming the bulk region in the second well:
forming an interlayer dielectric layer on the substrate; and
forming a contact layer on the interlayer dielectric layer.

6. The method of claim 1, wherein the first conductive type is P-type and the second conductive type is N-type.

7. The method of claim 1, wherein the first conductive type is N-type and the second conductive type is P-type.

8. The method of claim 1, wherein the insulation layer is formed as a field oxide layer.

9. The method of claim 1, wherein the insulation layer is formed in a shallow trench isolation structure.

10. The method of claim 1, wherein a length of the first insulation portion is different from a length of the second insulation portion.

11. A semiconductor device, comprising:
a substrate having a first conductive type;
a high-voltage well having a second conductive type and disposed in the substrate;
a drift region disposed in the high-voltage well;
a partial insulation structure disposed on edge portions of the drift region; and
a drain region disposed in the high-voltage well and spaced apart from the drift region.

12. The semiconductor device of claim 11, wherein the drift region includes a plurality of alternately arranged first sections and second sections,
each first section includes a top region having the first conductive type and a grade region having the second conductive type, and
each second section includes the grade region.

13. The semiconductor device of claim 11, wherein the first conductive type is P-type and the second conductive type is N-type.

14. The semiconductor device of claim 11, further including:
a first well having the first conductive type disposed on the high-voltage well, close to an edge portion of the high-voltage well, and spaced apart from the drift region;
a second well having the first conductive type outside the high-voltage well and adjacent to the edge portion of the high-voltage well;
a source region disposed in the first well;
a gate oxide layer disposed on the substrate between the first well and the drift region; and
a gate layer disposed on the gate oxide.

15. The semiconductor device of claim 11, wherein the partial insulation structure is formed of field oxide.

16. The semiconductor device of claim 11, further including:
an interlayer dielectric layer disposed on a top portion of the drift region; and
a contact layer disposed on the interlayer dielectric layer.

17. The semiconductor device of claim 14, further including a bulk region disposed in the second well.

18. The semiconductor device of claim 11, wherein the first conductive type is N-type and the second conductive type is P-type.

19. The semiconductor device of claim 11, wherein the partial insulation structure includes:
a first insulation portion covering a first edge portion of the drift region; and
a second insulation portion covering a second and opposite edge portion of the drift region.

20. The semiconductor device of claim 11, wherein the partial insulation structure does not cover a central portion of the drift region.
